(19) United States
(12) Patent Application Publication
(10) Pub. No.: US 2005/0196907 A1
(43) Pub. Date: Sep. 8, 2005

(54) Underfill system for die-over-die arrangements

(76) Inventors: Glenn Ratificar, Gilbert, AZ (US); Song-Hua Shi, Phoenix, AZ (US); Edward L. Ramsay, Chandler, AZ (US)

Correspondence Address: BUCKLEY, MASCHOFF, TALWALKAR LLC, 5 ELM STREET, NEW CANAAN, CT, 06840, US

(21) Appl. No.: 10/667,798

(22) Filed: Sep. 19, 2003

(51) Int. Cl. H01L 21/48; H01L 23/48

(52) U.S. Cl. 438/126; 438/127; 257/787

(57) ABSTRACT

A system may include a first integrated circuit die, no-flow underfill material, and a second integrated circuit die. A first side of the first integrated circuit die may include a first plurality of electrical contacts, and the underfill material may contact the first side of the first integrated circuit die. A first side of the second integrated circuit die may include a second plurality of electrical contacts, and the first side of the second integrated circuit die may also contact the no-flow underfill material.

### BACKGROUND

Many systems exist for coupling an integrated circuit (IC) die to a substrate such as an IC package. An IC die may be electrically coupled to a substrate by soldering an array of electrical contacts located on the die directly to electrical contacts located on the substrate. This electrical coupling might not result in satisfactory mechanical coupling between the IC die and the substrate.

Underfill material may be used to improve mechanical coupling between the IC die and the substrate. Underfill material encapsulates the electrical connections between the die and the substrate and may therefore protect the connections from exposure to environmental hazards. Moreover, the coefficient of thermal expansion (CTE) of the IC die may differ from the CTE of the substrate so as to cause undue stress on the electrical connections during thermal excursion. Underfill encapsulants may address this mismatch by distributing the stress away from the connections. However, satisfactory systems have not been proposed for providing underfill to a system in which a bottom side of a first IC die is coupled to a substrate and a bottom side of a second IC die is coupled to a top side of the first IC die.

### BRIEF DESCRIPTION OF THE DRAWINGS

FIG. 1 is a side elevation of a device according to some embodiments.

FIG. 2 is diagram of a process to fabricate the FIG. 1 device according to some embodiments.

FIG. 3 is a bottom view of an IC die according to some embodiments.

FIG. 4 is a top view of an IC die according to some embodiments.

FIG. 5 is diagram of a process to fabricate the FIG. 1 device according to some embodiments.

FIG. 6 is a side elevation of a substrate according to some embodiments.

FIG. 7 is a side elevation of a substrate and an IC die according to some embodiments.

FIG. 8 is a side elevation of a substrate and an IC die according to some embodiments.

FIG. 9 is a side elevation of a substrate, an IC die, and underfill material according to some embodiments.

FIG. 10 is a side elevation of a substrate, an IC die, and underfill material according to some embodiments.

FIG. 11 is a side elevation of a substrate, an IC die, underfill material between the substrate and the IC die, and underfill material placed on the IC die according to some embodiments.

FIG. 12 is a side elevation of a substrate, an IC die, underfill material between the substrate and the IC die, underfill material placed on the IC die, and a second IC die according to some embodiments.

FIG. 13 is a diagram of a system according to some embodiments.

### DETAILED DESCRIPTION

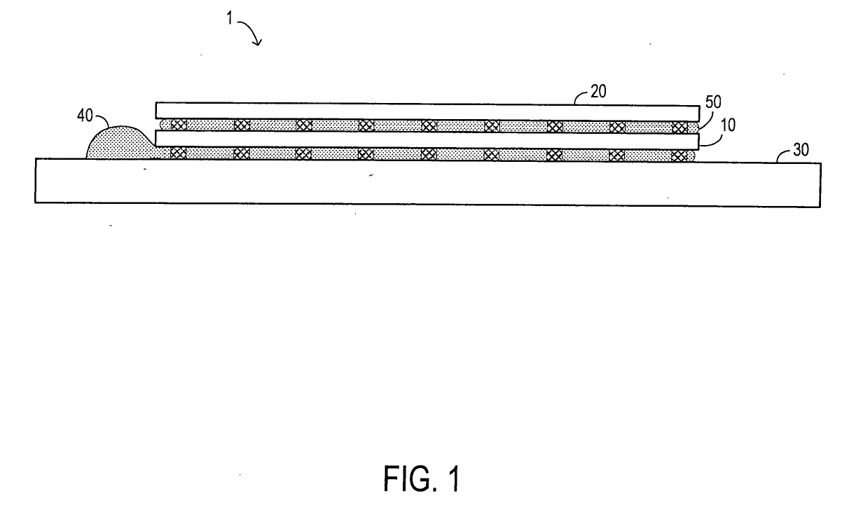

FIG. 1 is a side elevational view of device 1 according to some embodiments. Device 1 includes IC die 10, IC die 20, and substrate 30. Underfill material 40 is disposed between IC die 10 and substrate 30, while underfill material 50 is disposed between IC die 10 and IC die 20.

IC die 10 includes integrated electrical devices and may be fabricated using any suitable substrate material and fabrication techniques. IC die 10 may provide one or more functions. In some embodiments, IC die 10 comprises a microprocessor chip having a silicon substrate.

IC die 20 may include integrated electrical devices and any suitable substrate material. IC die 20 may also be fabricated according to any suitable fabrication techniques. IC die 20 may provide any functions, including but not limited to memory cache functions. In the illustrated embodiment, a length and a width of IC die 20 are substantially equally to a length and a width of IC die 10. A length and a width of IC die 20 may be less than or greater than a length and a width of IC die 10 according to some embodiments.

Substrate 30 may comprise an IC package, a circuit board, or other substrate. Substrate 30 may therefore comprise any ceramic, organic, and/or other suitable material. Substrate 30 may carry power and/or I/O signals between IC die 10 and external electrical components. Substrate 30 may also transmit and receive signals directly to and from IC die 20 according to some embodiments.

Underfill material 40 is in contact with a side of IC die 10 and with substrate 30. Underfill material 40 is a capillary flow underfill material according to some embodiments. Examples of such underfill material include STAYCHIP™ 3080 by Cookson Electronics—Semiconductor Products and Shin-Etsu product no. X-43-5107, but embodiments are not limited to these examples or even to materials similar thereto. Generally, capillary flow underfill material is placed next to an IC die-substrate interface and is “pulled” into the interface by surface energy and/or capillary action. Energy may then be applied to the underfill material to transform the material into a protective inert polymer. Some embodiments may utilize no-flow underfill material between IC die 10 and substrate 30.

In this regard, underfill material 50 may comprise no-flow underfill material. No-flow underfill material may comprise thermally-polymerizable liquid resin systems that include fluxing functional groups. Non-exhaustive examples include STAYCHIP™ DP-0115 by Cookson Electronics—Semiconductor Products. As shown, underfill material 50 is in contact with another side of IC die 10 and a side of IC die 20.

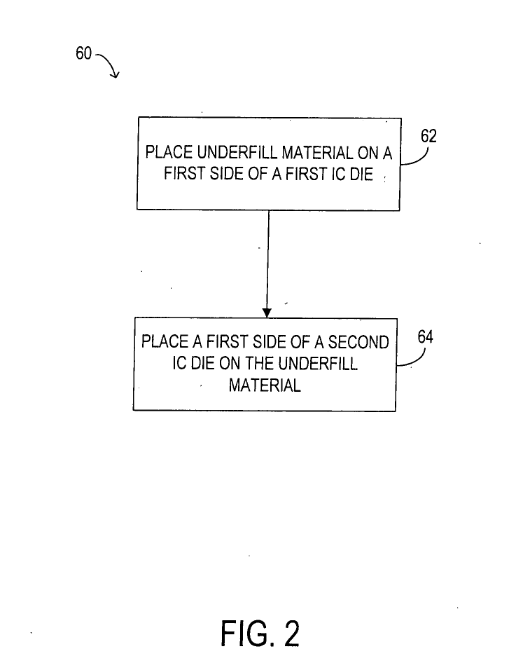

FIG. 2 is a diagram of process 60 according to some embodiments. Process 60 may be executed by one or more fabrication devices, and all or a part of process 60 may be executed manually. Process 60 may be executed soon after fabrication of IC die 10 and IC die 20 or may be executed significantly later. An example of the latter scenario may occur if a first company fabricates one or more of IC die 10, IC die 20, and substrate 30, and if a second company performs process 60 of FIG. 2. In some embodiments, process 60 is executed after IC die 10 is coupled to substrate 30 as shown in FIG. 1.

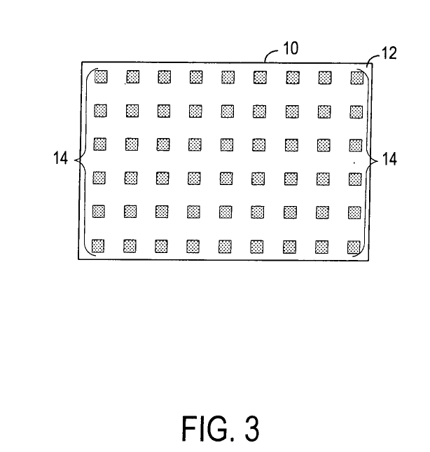

Initially, at 62, underfill material is placed on a first side of a first IC die. IC die 10 will be considered the first IC die in the present example. FIG. 3 illustrates first side 12 of IC die 10 according to some embodiments.

First side 12 of IC die 10 includes electrical contacts 14. Electrical devices that are integrated into IC die 10 may reside between a substrate of IC die 10 and electrical contacts 14. In some embodiments, such a substrate resides between the electrical devices and electrical contacts 14.

Electrical contacts 14 may comprise gold and/or nickel-plated copper contacts fabricated upon IC die 10. Electrical contacts 14 may comprise Controlled Collapse Chip Connect (C4) solder bumps. In this regard, conductive contacts 14 may be recessed under, flush with, or extending above first side 12 of IC die 10. Electrical contacts 14 may be electrically coupled to the electrical devices that are integrated into IC die 10.

Underfill 50 may be placed on first side 12 by a linear pump (not shown). A position and volume of underfill 50 may be determined so as to result in the arrangement shown in FIG. 1 after compression and curing thereof.

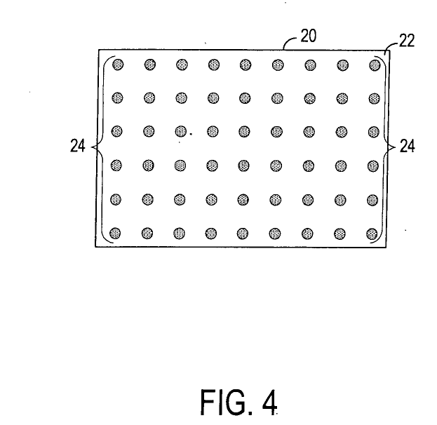

FIG. 4 illustrates first side 22 of IC die 20 according to some embodiments. First side 22 of IC die 20 includes electrical contacts 24. IC die 20 may comprise a flip chip arrangement in which electrical devices that are integrated therein reside between a substrate of IC die 20 and electrical contacts 24. The substrate of IC die 20 resides between the electrical devices and electrical contacts 24 in other embodiments. Electrical contacts 24 may comprise C4 solder bumps or plated copper contacts. Electrical contacts 24 may be recessed under, flush with, or extending above first side 22 of IC die 20, and may be electrically coupled to the electrical devices that are integrated into IC die 20. Although the embodiments of FIGS. 3 and 4 show electrical contacts 14 and 24 as having substantially square or circular cross section, respectively, in other embodiments one or more of electrical contacts 14 and 24 have cross sections of different and/or varying shapes.

First side 22 of IC die 20 is placed on underfill material 50 at 64. Some embodiments of process 60 may therefore provide underfill protection to the interface between IC die 10 and IC die 20 in a more efficient manner than previously available. In one example, process 64 may allow the dimensions of IC die 20 to equal or exceed the dimensions of IC die 10.

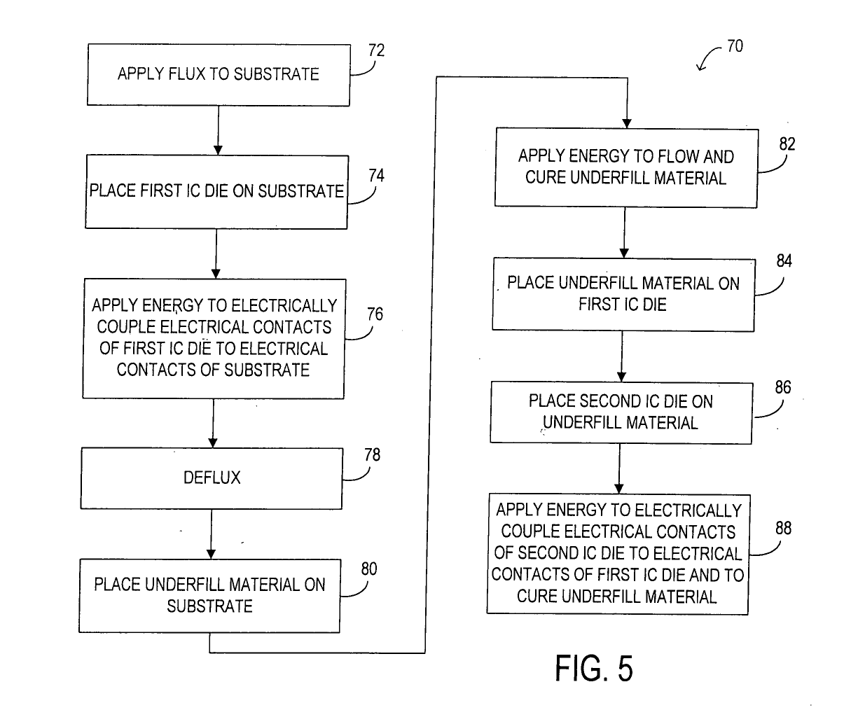

FIG. 5 is a diagram of process 70 to fabricate device 1 according to some embodiments. Process 70 may be executed manually and/or by one or more fabrication devices. Process 70 may be executed by an entity different from the entity or entities responsible for fabricating IC die 10 and IC die 20.

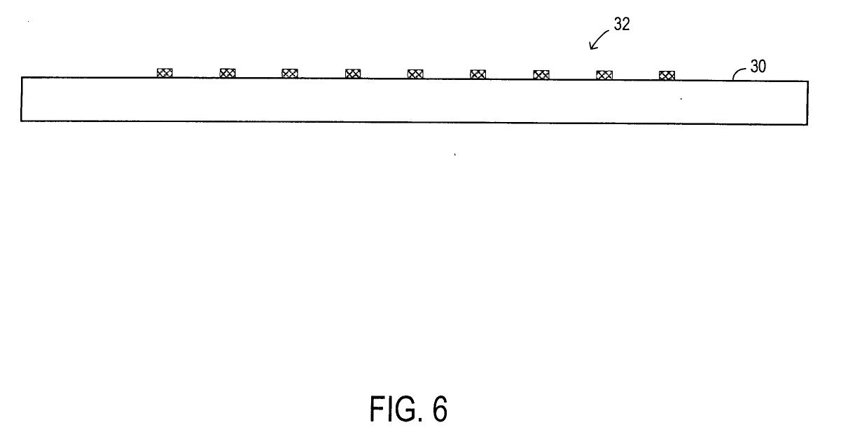

Flux is applied to substrate 30 at 72. FIG. 6 is a side elevational view of substrate 30 showing electrical contacts 32. Electrical contacts 32 may comprise any of the contact types described above, or other contact types.

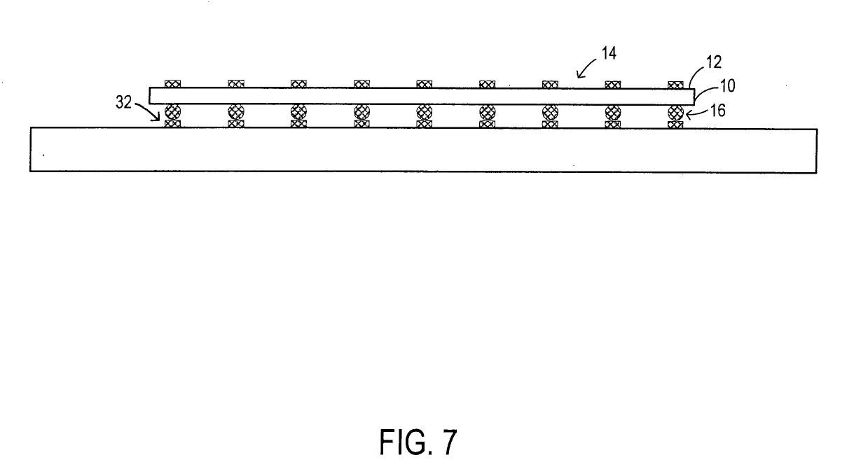

A side of IC die 10 is placed on substrate 30 at 74. FIG. 7 shows IC die 10 and substrate 30 after 74 according to some embodiments. IC die 10 includes first side 12 and electrical contacts 14 as described with respect to FIG. 3. IC die 10 also includes electrical contacts 16, which may comprise C4 solder balls as described with respect to FIG. 4. Electrical contacts 16 and electrical contacts 32 may be disposed such that a plurality of electrical contacts 16 contact respective ones of electrical contacts 32.

At 76, energy is applied to electrical contacts 16 and to electrical contacts 32 to electrically couple ones of electrical contacts 16 to respective ones of electrical contacts 32. The energy may comprise thermal energy received from a reflow oven through which the elements of FIG. 7 are passed, energy received from a laser, and/or any other energy received from any other source.

The energy is described above as electrically coupling the contacts. However, in some embodiments such as that shown in FIG. 7, an electrical connection already exists between the electrical contacts prior to application of the energy. According to some embodiments, the electrical coupling caused by the energy comprises forming a new electrical connection between one of contacts 16 and one of contacts 32 by reflowing solder that is attached thereto into a single integral conductor. The flux placed on electrical contacts 32 prior to 74 may deoxidize the metal surfaces of electrical contacts 32 and electrical contacts 16 during such reflowing to assist in creating the conductor. In some embodiments, the flux is additionally or alternatively placed on electrical contacts 16 prior to 74.

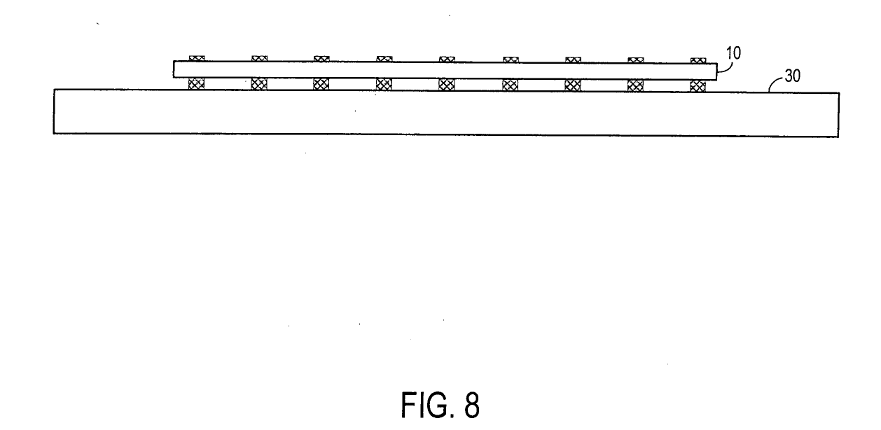

FIG. 8 shows IC die 10 and substrate 30 after energy is applied at 76. Respective ones of electrical contacts 16 and electrical contacts 32 are shown formed into single integral conductors. The flux applied at 72 may cause a residue to form at the interface of IC die 10 and substrate 30 after 76. Accordingly, some embodiments include defluxing the interface at 78. Defluxing may proceed according to any currently- or hereafter-known system, and the particular defluxing system may depend upon the various compositions of the flux applied at 72, electrical contacts 16, electrical contacts 32, underfill 40, substrate 30, and/or IC die 10. For example, solvent- or aqueous-based cleaners may be used at 78.

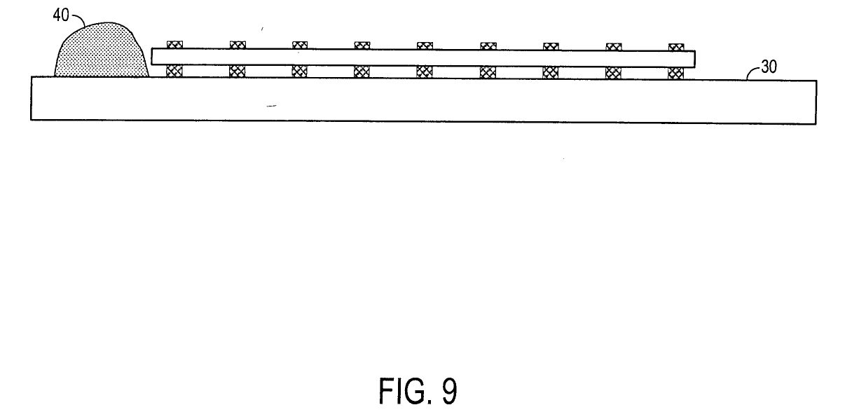

Underfill material 40 is placed on substrate 30 at 80. FIG. 9 illustrates the placement of underfill material 40 on substrate 30. Underfill material may be dispensed by a linear pump, a rotary positive displacement pump, or by other means. Any suitable technique for placing underfill material 40 on substrate 30 may be employed. In some embodiments, underfill material 40 is dispensed on substrate 30 substantially entirely around a perimeter of IC die 10.

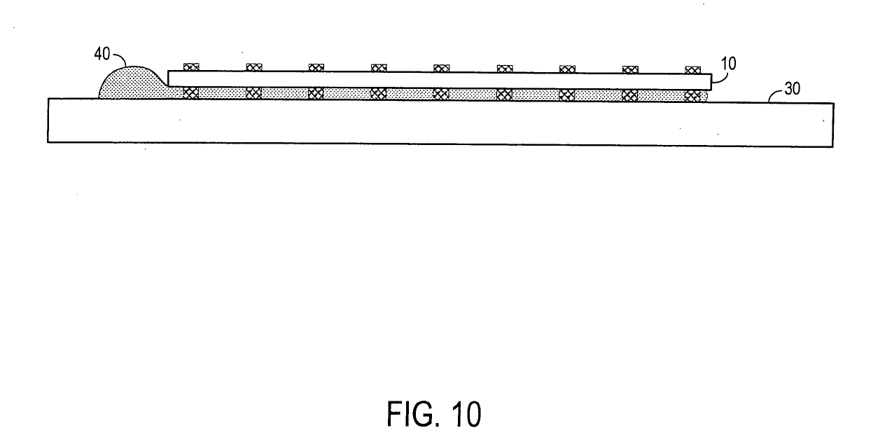

Next, at 82, energy is applied to underfill material 40 in order to flow underfill material 40 between the interface of IC die 10 and substrate 30 and to cure the flowed underfill material 40. The energy may comprise thermal energy provided by a reflow oven. Currently- or hereafter-known techniques may be used to determine a suitable heating profile based on the dimensions of the interface, the composition and viscosity of underfill material 40, and other factors. FIG. 10 illustrates IC die 10, substrate 30, and underfill material 40 after energy is applied at 82 according to some embodiments.

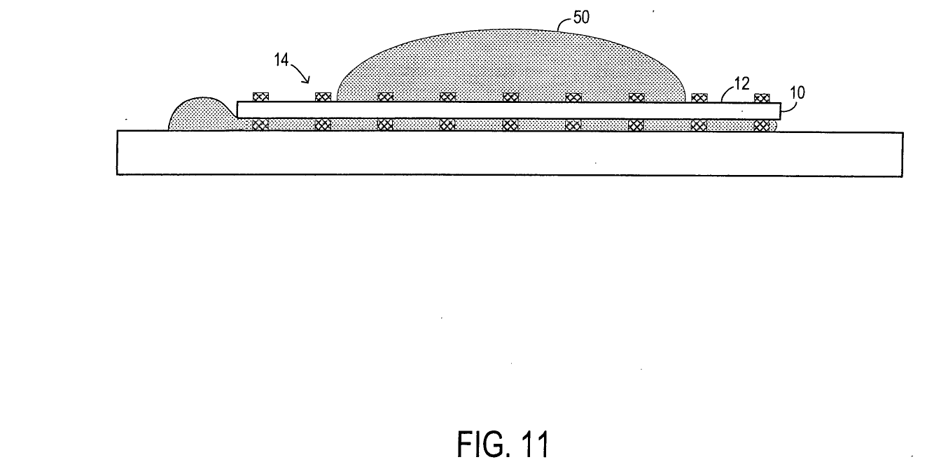

Underfill material 50 is placed on side 12 of IC die 10 at 84. As shown in FIG. 11, underfill material may cover one or more of electrical contacts 14 after being placed on IC die 10. Underfill material 50 may comprise a no-flow underfill material. Underfill material 50 may be placed according to currently- or hereafter-known techniques for determining a volume and position of no-flow underfill material for use in protecting an interface.

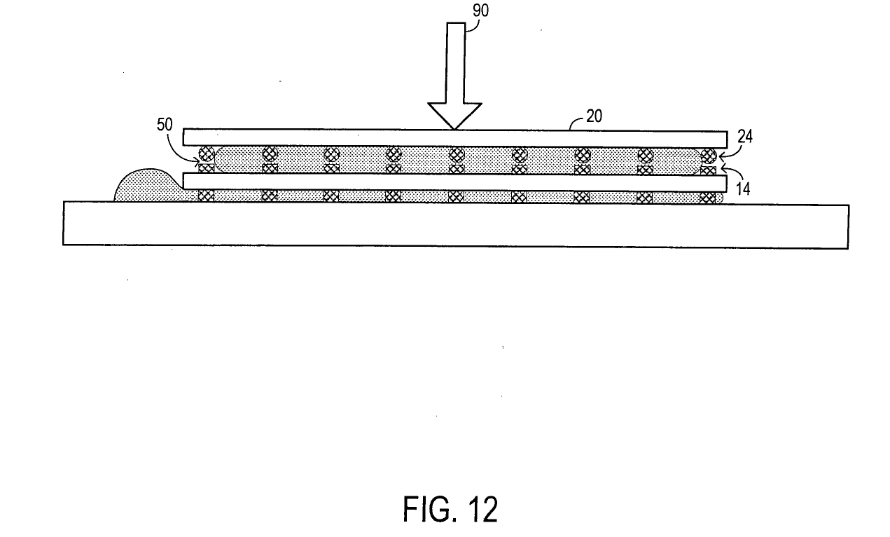

IC die 20 is placed on underfill material 50 at 86. In some embodiments, IC die 20 is compressed downward at 86 by force 90 shown in FIG. 12. The force may be applied by a pick-and-place machine or by a thermal compression bonding machine. The force may cause underfill material 50 to deform as illustrated. FIG. 12 also shows that IC die 20 may be placed on underfill material 50 so as to position a plurality of electrical contacts 24 directly over respective ones of electrical contacts 14. The plurality of electrical contacts 24 may therefore contact the respective ones of electrical contacts 14 due to force 90.

Next, at 88, energy is applied to underfill material 50, electrical contacts 24, and electrical contacts 14 to electrically couple ones of electrical contacts 24 to respective ones of electrical contracts 14. The applied energy may also cure underfill material 50 so as to transform underfill material into an inert protective polymer. In some embodiments, the energy is applied at 88 by a thermal compression bonding machine in contact with IC die 20 so as to first reflow the solder and to then cure underfill material 50. Force 90 may be applied during the application of energy at 88, or may be removed before or during the application of energy at 88. One system for placing a component on no-flow underfill material and for electrically coupling the component to a second component disposed under the no-flow underfill material is described in commonly-assigned and co-pending U.S. patent application Ser. No. ______ (Intel Docket No. P12099), entitled ELECTRONIC ASSEMBLY WITH FILLED NO-FLOW UNDERFILL AND METHODS OF MANUFACTURE and filed on ______. Device 1 of FIG. 1 illustrates the elements of FIG. 12 after 88 according to some embodiments.

As described above, the electrical contacts may be electrically coupled prior to application of the energy. According to some embodiments, the electrical coupling caused by the energy applied at 88 comprises forming a new electrical connection between at least one of contacts 24 and at least one of contacts 14 by reflowing solder that is attached thereto into a single integral conductor. Underfill material 50 may include fluxing capability to remove metal oxides from the contacts before the contacts are soldered together.

According to some embodiments, underfill material 40 comprises no-flow underfill material. Underfill material 40 is therefore placed on substrate 30 prior to placing IC die 10 on substrate 30 in some of these embodiments. Moreover, the separate fluxing and defluxing at 72 and 78 that is described above might be avoided if underfill material 40 also provides fluxing and defluxing action.

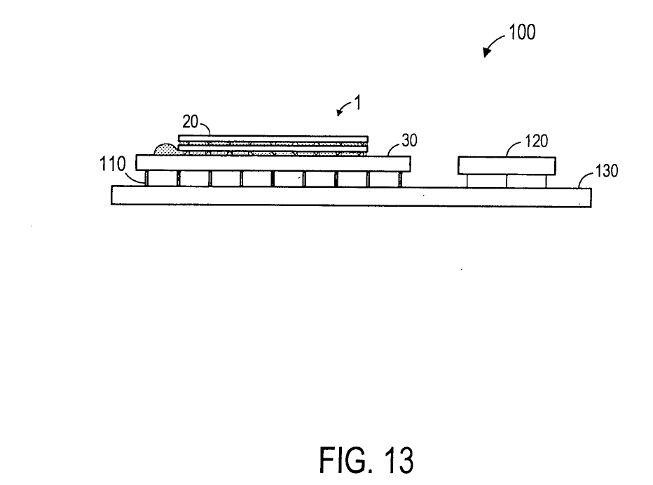

FIG. 13 is a side elevation of system 100 according to some embodiments. System 100 may comprise components of a server platform. System 100 includes device 1 as described above, memory 120 and motherboard 130. Device 1 of system 100 may comprise a microprocessor, with IC die 20 of device 1 comprising a memory cache.

Substrate 30 of device 1 may comprise an IC package having through-hole pins 110 that are electrically coupled to conductive contacts 32. Accordingly, pins 110 may carry signals such as power and I/O signals between elements of device 1 and external devices. For example, pins 110 may be mounted directly on motherboard 130 or onto a socket (not shown) that is in turn mounted directly to motherboard 130. Motherboard 130 may therefore electrically couple memory 120 to device 1. More particularly, motherboard 130 may comprise a memory bus (not shown) that is electrically coupled to pins 110 and to memory 120. Memory 120 may comprise any type of memory for storing data, such as a Single Data Rate Random Access Memory, a Double Data Rate Random Access Memory, or a Programmable Read Only Memory.

The several embodiments described herein are solely for the purpose of illustration. The various features described herein need not all be used together, and any one or more of those features may be incorporated in a single embodiment. Some embodiments may include any currently or hereafter-known versions of the elements described herein. Therefore, persons skilled in the art will recognize from this description that other embodiments may be practiced with various modifications and alterations.

1. A method comprising:
placing underfill material on a first side of a first integrated circuit die, the first side of the first integrated circuit die comprising a first plurality of electrical contacts; and
placing a first side of a second integrated circuit die on the underfill material, the first side of the second integrated circuit die comprising a second plurality of electrical contacts.

2. A method according to claim 1, further comprising:
applying energy to the underfill material and to the first and second plurality of electrical contacts to electrically couple ones of the first plurality of electrical contacts and respective ones of the second plurality of electrical contacts, and to cure the underfill material.

3. A method according to claim 2, wherein applying the energy comprises:
applying energy to first electrically couple ones of the first plurality of electrical contacts and respective ones of the second plurality of electrical contacts, and to then cure the underfill material.

4. A method according to claim 2, wherein applying the energy comprises:
applying energy to the underfill material to perform fluxing on one or more of the first plurality of electrical contacts and on one or more of the second plurality of electrical contacts.

5. A method according to claim 1, farther comprising:
bonding a second side of the first integrated circuit die to a substrate.

6. A method according to claim 5, wherein the second side of the first integrated circuit die comprises a third plurality of electrical contacts, wherein the substrate comprises a fourth plurality of electrical contacts, and wherein bonding the second side of the first integrated circuit die to the substrate comprises:
placing second underfill material on the substrate;
placing the second side of the first integrated circuit die on the second underfill material; and
applying second energy to the second underfill material and to the third and fourth plurality of electrical contacts to electrically couple ones of the third plurality of electrical contacts and respective ones of the fourth plurality of electrical contacts, and to cure the second underfill material.

7. A method according to claim 5, wherein the second side of the first integrated circuit die comprises a third plurality of electrical contacts, wherein the substrate comprises a fourth plurality of electrical contacts, and wherein bonding the second side of the first integrated circuit die to the substrate comprises:
applying flux to the fourth plurality of electrical contacts;
placing the second side of the first integrated circuit die on the substrate;
applying second energy to the third and fourth plurality of electrical contacts to electrically couple ones of the third plurality of electrical contacts and respective ones of the fourth plurality of electrical contacts;
placing second underfill material on the substrate; and
applying third energy to the second underfill material to promote capillary flow of the second underfill material between the first integrated circuit die and the substrate, and to cure the flowed second underfill material.

8. A method according to claim 1, wherein the first side of the second integrated circuit die comprises first integrated devices.

9. A method according to claim 8, wherein a second side of the first integrated circuit die comprises second integrated devices.

10. A method according to claim 1, wherein the underfill material is no-flow underfill material.

11. A method according to claim 1, wherein a length and a width of the second integrated circuit die are substantially equal to a length and a width of the first integrated circuit die.

12. A method according to claim 1, wherein a length of the second integrated circuit die is greater than a length of the first integrated circuit die, and wherein a width of the second integrated circuit die is greater than a width of the first integrated circuit die.

13. A device comprising:
a first integrated circuit die, a first side of the first integrated circuit die comprising a first plurality of electrical contacts;
no-flow underfill material in contact with the first side of the first integrated circuit die; and
a second integrated circuit die, a first side of the second integrated circuit die comprising a second plurality of electrical contacts, and the first side of the second integrated circuit die in contact with the no-flow underfill material.

14. A device according to claim 13, the first integrated circuit die comprising a second side, the device further comprising:
second underfill material in contact with the second side of the first integrated circuit die; and
a substrate in contact with the second underfill material.

15. A device according to claim 14,
wherein the second side of the first integrated circuit die comprises a third plurality of electrical contacts,
wherein the substrate comprises a fourth plurality of electrical contacts, and
wherein ones of the fourth plurality of electrical contacts are electrically coupled to respective ones of the third plurality of electrical contacts.

16. A device according to claim 14, wherein the second underfill material comprises no-flow underfill material.

17. A device according to claim 14, wherein the second underfill material comprises capillary flow underfill material.

18. A device according to claim 13, wherein the no-flow underfill material comprises fluxing functional groups.

19. A device according to claim 13, wherein the first side of the second integrated circuit die comprises first integrated devices.

20. A device according to claim 19, wherein a second side of the first integrated circuit die comprises second integrated devices.

21. A device according to claim 13, wherein a length and a width of the second integrated circuit die are substantially equal to a length and a width of the first integrated circuit die.

22. A device according to claim 13, wherein a length of the second integrated circuit die is greater than a length of the first integrated circuit die, and wherein a width of the second integrated circuit die is greater than a width of the first integrated circuit die.

23. A device according to claim 13, wherein the second integrated circuit die comprises a memory cache.

24. A system comprising:
a microprocessor comprising:
a first integrated circuit die, a first side of the first integrated circuit die comprising a first plurality of electrical contacts;
no-flow underfill material in contact with the first side of the first integrated circuit die; and
a second integrated circuit die, a first side of the second integrated circuit die comprising a second plurality of electrical contacts, and the first side of the second integrated circuit die in contact with the no-flow underfill material; and
a double data rate memory electrically coupled to the microprocessor.

25. A system according to claim 24, the first integrated circuit die comprising a second side, the system further comprising:
second underfill material in contact with the second side of the first integrated circuit die; and
a substrate in contact with the second underfill material.

26. A system according to claim 25,
wherein the second side of the first integrated circuit die comprises a third plurality of electrical contacts,
wherein the substrate comprises a fourth plurality of electrical contacts,
wherein ones of the fourth plurality of electrical contacts are electrically coupled to respective ones of the third plurality of electrical contacts, and
wherein ones of the fourth plurality of electrical contacts are electrically coupled to the memory.

27. A system according to claim 24, wherein the second integrated circuit die comprises a memory cache.

28. A system according to claim 24, wherein a length and a width of the second integrated circuit die are substantially equal to a length and a width of the first integrated circuit die.

29. A system according to claim 24, wherein a length of the second integrated circuit die is greater than a length of the first integrated circuit die, and wherein a width of the second integrated circuit die is greater than a width of the first integrated circuit die.
